(19) United States
(12) Patent Application Publication
(10) Pub. No.: US 2025/0132124 A1
(43) Pub. Date: Apr. 24, 2025

(54) MULTI-BEAM CHARGED PARTICLE MICROSCOPE DESIGN WITH MIRROR FOR FIELD CURVATURE CORRECTION

(71) Applicant: Carl Zeiss MultiSEM GmbH, Oberkochen (DE)

(72) Inventors: Dirk Zeidler, Oberkochen (DE); Thomas Schmid, Aalen (DE); Wolfgang Singer, Aalen (DE)

(21) Appl. No.: 19/006,028

(22) Filed: Dec. 30, 2024

Related U.S. Application Data
(63) Continuation of application No. PCT/EP2023/025289, filed on Jun. 21, 2023.

(30) Foreign Application Priority Data
Jul. 7, 2022 (DE) 10 2022 206 937.4

(51) Int. Cl. H01J 37/22; H01J 37/28

(52) U.S. Cl. CPC H01J 37/226; H01J 37/28; H01J 2237/0435; H01J 2237/15; H01J 2237/153

(57) ABSTRACT

A multi-beam charged particle system can have reduced field curvature. The multi-beam charged particle system can comprise a charged particle mirror element for compensating a field curvature of charged particle imaging elements. The charged particle mirror element can be configured for generating during use a virtual reflection surface of curved shape for reflecting primary charged particles. The disclosure can be applied for applications of multi-beam charged particle system, where higher beam uniformity and throughput are desired.

### CROSS-REFERENCE TO RELATED APPLICATIONS

The present application is a continuation of, and claims benefit under 35 USC 120 to, international application No. PCT/EP2023/025289, filed Jun. 21, 2023, which claims benefit under 35 USC 119 of German Application No. 10 2022 206 937.4, filed Jul. 7, 2022. The entire disclosure of each of these applications is incorporated by reference herein.

### FIELD

The disclosure relates to a multi-beam charged particle microscope design with a mirror as a design mechanism for correction of field curvature.

### BACKGROUND

WO 2005/024881 A2 discloses an electron microscope system which operates with a multiplicity of electron beamlets for the parallel scanning of an object to be inspected with a bundle of electron beamlets. The bundle of primary charged particle beamlets is generated by directing a primary charged particle beam onto a multi-beam forming unit, comprising at least one multi-aperture plate, which has a multiplicity of openings. One portion of the electrons of the electron beam is incident onto the multi-aperture plate and is absorbed there, and another portion of the beam transmits the openings of the multi-aperture plate and thereby in the beam path downstream of each opening an electron beamlet is formed whose cross section is defined by the cross section of the opening. Furthermore, suitably selected electric fields which are provided in the beam path upstream and/or downstream of the multi-aperture plate cause each opening in the multi-aperture plate to act as a lens on the electron beamlets passing the opening so that each electron beamlet is focused and focus spots are formed in a surface which lies at a distance from the multi-aperture plate. The surface in which the foci of the electron beamlets are formed is imaged by downstream optics onto the surface of the object or sample to be inspected. The primary charged particle beamlets trigger secondary electrons or backscattered electrons to emanate as secondary electron beamlets from the object, which are collected and imaged onto a detector. Each of the secondary beamlets is incident onto a separate detector element so that the secondary electron intensities detected therewith provide information relating to the sample at the location where the corresponding primary beamlet is incident onto the sample. The bundle of primary beamlets is scanned systematically over the surface of the sample and an electron microscopic image of the sample is generated in the usual way for scanning electron microscopes. The resolution of a scanning electron microscope is generally limited by the focus diameter of the primary beamlets incident onto the object. Consequently, in multi-beam electron microscopy all the beamlets should generally form the same small focus spot on the object.

Multi-beam microscopes for wafer inspection form a plurality of focus spots of the plurality of primary charged particle beamlets on a wafer surface. The imaging lenses can generate a field curvature, which can lead to a deviation of the plurality of primary focus points from the planar wafer surface. The field curvature can therefor leads to relatively large deviations of the focus spot sizes on a wafer surface. With increasing demands in throughput of an inspection tasks and the corresponding increasing number of charged particle beamlets, also the field size generally increases and a deviation due to a field curvature generally increases.

In certain known systems, it was considered to compensate the field curvature by at least one micro-optical element formed as an integral part of the multi-beam forming unit. The multi-aperture plates with electrodes are typically formed by layer deposition and etching techniques, and a stack of different layers is formed. For a larger stroke, higher voltages can be provided to the electrostatic lenses. Inhomogeneities of the layer deposition and leakages of electrical fields can lead to inhomogeneous electron optical properties of the electrostatic elements over a multi-aperture plate. In multi-aperture stacks, the optical performance is typically limited. Within multi-beam forming units, it can be difficult to reach sufficient stroke for individually changing the focus positions of each primary charged particle beamlet with high accuracy, as desired for wafer inspection tasks.

US 2014/0158902 A1 discloses a particle-optical arrangement for a multi-beam system. A charged particle mirror element is not disclosed.

US 2011/0291021 A1 relates to a single beam system and discloses an apparatus for reflection electron beam lithography. The apparatus includes an electron source, a patterned electron reflector generator structure, a stage, a demagnifying electron lens, and an ExB separator. The ExB separator is configured to bend a trajectory of the electron beam towards the dynamic pattern generator structure. The patterned electron reflector structure is configured to reflect select portions of the electron beam so as to form a patterned electron beam. The ExB separator is further configured to allow the patterned electron beam to pass straight through towards the demagnifying electron lens. The demagnifying electron lens is configured to demagnify the patterned electron beam and project the demagnified patterned electron beam onto the target substrate.

### SUMMARY

The present disclosure seeks to provide a charged particle beam system which operates with a multiplicity of charged particle beams and can be used to achieve a higher imaging performance, such as a better resolution and narrower range of resolution for each beamlet of the plurality of beamlets. The disclosure also to provide a multi-beam charged particle beam system with reduced field curvature.

A multi-beam charged particle system with reduced field curvature can comprise a design mechanism for compensating field curvature aberrations introduced by the charged particle imaging elements.

The apparatus disclosed herein can have a straight projection axis and can substantially reduce the electron beam path by a factor of three-to-one (compared to a prior apparatus which uses a magnetic prism).

According to an aspect, the disclosure provides a multi-beam charged particle system comprising a charged particle beam source for generating a primary charged particle beam, a multi-beam forming unit for forming a plurality of primary charged particle beamlets from the primary charged particle beam, and an imaging system for forming a plurality of focus spots of the plurality of primary charged particle beamlets on a surface of a planar object. The imaging system comprises at least one lens element comprising an objective lens and at least one field lens. The imaging system further comprises a charged particle mirror element, the mirror element being configured for compensating during use a field curvature of the plurality of lens elements. The charged particle mirror element contributes to a field curvature of the imaging system with an opposite sign of the contribution of the at least one lens element to the field curvature. Thereby, with a design with a charged particle mirror element it is possible to compensate the contribution of the at least one lens element to the field curvature. With the reduced field curvature, a focus deviation of the primary charged particle beamlets from a planar object plane is reduced and a desired predetermined resolution can be achieved for a larger field size or a larger number of primary charged particle beamlets. Thereby, a larger field size with a larger number or primary charged particle beamlets can be utilized for an inspection task and a throughput of an inspection task is improved.

The multi-beam charged particle system further comprises a control unit. The control unit is configured for providing during use at least one voltage the charged particle mirror element. The charged particle mirror element and the voltages being configured to generate during can use a reflecting lens field with a virtual reflection surface of positive or collecting power. The primary charged particles can be decelerated and returned or reflected at the virtual reflection surface of the reflecting lens field.

In an example, the charged particle mirror element comprises at least three electrodes, comprising at least a first and a second ring shaped electrode and a surface electrode. The electrodes are connected to the control unit, and the control unit is configured for providing during use a first voltage U1 to the first ring shaped electrode, a second voltage U2 to the second ring shaped electrode and a mirror voltage Um to the mirror electrode. The voltages can be configured to generate during use a reflecting lens field with a virtual reflection surface of positive or collecting power. In an example, the surface electrode has a curved shape. In an example, the surface electrode is a segmented electrode comprising a plurality of N electrode segments, and wherein the control unit is further configured for providing during use a plurality of mirror voltages Um1 to UmN to the plurality of N electrode segments. In an example, the charged particle mirror element comprises a third electrode connected to the control unit, the control unit being further configured for providing during use a third voltage U3 to the third ring shaped electrode. The examples can also be combined. With the examples, the virtual reflection surface of curved shape with positive or collecting power can be formed. The primary charged particle beamlets can be reflected at the virtual reflection surface.

In an example, the charged particle mirror element is arranged in a plane where the plurality of primary charged particle beamlets are at least partially overlapping. In an example, the charged particle mirror element is arranged in a pupil plane. In an alternative example, the charged particle mirror element is arranged in proximity of an intermediate field plane, where a plurality of focus spots of the primary charged particle beamlets are formed. In an example, the charged particle mirror element comprises a plurality of multi-aperture plates with a plurality of apertures, configured to individually receive and reflect each individual primary charged particle beamlet of the plurality of primary charged particle beamlets. In an example, at least one multi-aperture plate is configured with a plurality of electrodes, and the control unit is configured to provide an individual voltage to each electrode for individual control of a reflecting position for each individual primary charged particle beamlet. Thereby, the virtual reflection surface of curved shape for the primary charged particle beamlets can be achieved, and each primary charged particle beamlet can be reflected at the virtual reflection surface. The multi-aperture plates configured for generating the virtual reflection surface of curved shape is however not limited to the example above, and for example at least one multi-aperture plate comprises a plurality of apertures of different diameter.

According to an example, a multi-beam charged particle system further comprises a secondary electron beam divider or beam splitter, configured for guiding secondary beamlets, which are generated at the focus spots of the plurality of primary beamlets at the surface of a planar object to a detector. A multi-beam charged particle system can further comprise a secondary electron imaging system comprising a plurality of charged particle-optical elements for forming focus spots of secondary electron beamlets on a detector plane. The secondary electron beam divider can comprise a divider segment for dividing the beam path of primary charged particle from the beam path of the secondary electrons. In an example, the secondary electron beam divider further comprises at least a first segment arranged in the beam path of primary charged particles and at least a second segment in the beam path of the secondary electrons, the first and the second segment being configured for compensating a dispersion and further aberrations of the divider segment.

According to a first embodiment of the disclosure, the charged particle mirror element is configured for a normal incidence of the plurality of primary beamlets, such that the reflected primary beamlets are propagating in parallel direction to the primary beamlets before incidence on the charged particle mirror element. The plurality of primary charged particle beamlets form a first path from the multi-beam forming unit to the charged particle mirror element and form a second path of the primary charged particle beamlets after reflection from the charged particle mirror element in direction of the at least one objective lens. In the first embodiment, in proximity of the charged particle mirror element, first and second beam paths are at least partially parallel to each other.

According to the first embodiment, the multi-beam charged particle system further comprises a primary charged particle beam divider for guiding the primary charged particle beamlets along a first beam path from the multi-beam forming unit to the charged particle mirror element. The primary charged particle beam divider is further configured for guiding the primary charged particle beamlets along the second beam path after reflection from the charged particle mirror element in direction of the at least one objective lens. In an example, the primary charged particle beam divider comprises a divider segment for dividing the first from the second beam path, at least a first segment arranged in the first beam path and at least a second segment in the second beam path, the first and the second segment being configured for compensating a dispersion and further aberrations of the divider segment.

According to an example, the primary charged particle beam divider and the secondary electron beam divider is formed as one integrated unit.

According to a second embodiment of the disclosure, the charged particle mirror element is configured for an oblique incidence. According to the second embodiment, the multi-beam charged particle system is configured for forming a first path from the multi-beam forming unit to the charged particle mirror element, and for forming a second path of the primary charged particle beamlets after reflection from the charged particle mirror element in direction of the at least one objective lens, wherein the first and second path are arranged at an angle exceeding 10°, for example 15° or 20°. In an example, the charged particle mirror element according to the second embodiment has an elliptical cross section.

According to a third embodiment of the disclosure, the multi-beam charged particle system further comprises a second charged particle mirror element, the first and the second mirror element being configured for jointly compensating during use a field curvature of the plurality of lens elements.

According to an example of an embodiment, the charged particle mirror element is further configured for compensating during use a further imaging aberration. Next to field curvature, other aberrations can be compensated with a charged particle mirror element. Such further aberration can be field dependent or field invariant. An example is a compensation of axial chromatic aberration or dispersion of the plurality of beamlets, or a compensation of a field-depending astigmatism or coma aberration.

In an aspect of the disclosure, a method of operation of the multi-beam charged particle system for a variable compensation of a field curvature is provided. The field curvature depends on a parameter setting of a multi-beam charged particle system, and the design of the charged particle mirror element and the voltages provided by a control unit to drive the charged particle mirror element are configured to variably compensate field curvature and optionally other aberrations.

By each of the embodiments or examples of the disclosure, a multi-beam charged particle beam system with reduced field curvature can be provided. The disclosure can therefore allow a wafer inspection with higher precision and with a lower variation of focus spot sizes of the focus spots on a wafer surface arranged in an object plane.

It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle system of the prior art;

FIG. 2 schematically illustrates a multi-beam charged particle system with a charged particle mirror element;

FIGS. 3A-3B illustrate an effect of a field curvature of a system of the prior art;

FIG. 4 illustrates an example according to the first embodiment of the disclosure;

FIGS. 5A-5B illustrate an effect of a design without field curvature with a system according to the first embodiment;

FIGS. 6A-6D illustrate some examples of a charged particle mirror element;

FIG. 7 illustrates an examples of a charged particle mirror element utilizing a plurality of multi-aperture plates;

FIG. 8 illustrates an example of a multi-beam charged particle system with a charged particle mirror element of FIG. 7;

FIG. 9 illustrates a charged particle beam divider element;

FIG. 10 illustrates a second embodiment of the disclosure;

FIGS. 11A-11B illustrate a charged particle mirror element for the second embodiment of the disclosure;

FIG. 12 illustrates a further example of the second embodiment of the disclosure;

FIGS. 13A-13C schematically illustrate further variations of the disclosure; and

FIG. 14 illustrated a method of operating a multi-beam charged particle system with a mirror corrector.

### DESCRIPTION OF EXEMPLARY EMBODIMENTS

In the exemplary embodiments of the disclosure described below, components similar in function and structure are indicated as far as possible by similar or identical reference numerals.

Some array elements, for example the plurality of primary charged particle beamlets, are identified by the reference number. Depending on the context, the same reference number may also identify a single element out or the array elements. Each primary charged particle beamlet 3.1, 3.2, 3.3 is one of the plurality of primary charged particle beamlets 3.

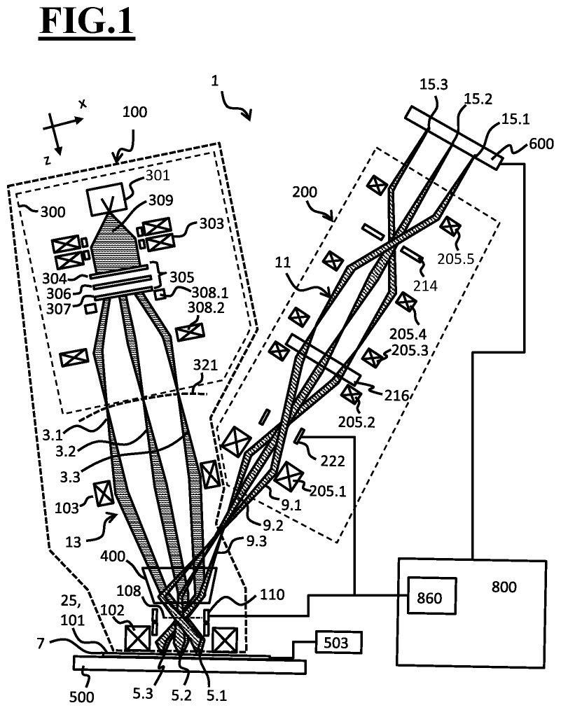

The schematic representation of FIG. 1 illustrates certain basic features and functions of a multi-beam charged-particle system 1. It is to be noted that the symbols used in FIG. 1 have been chosen to symbolize their respective functionality. The type of system shown is that of a multi-beam scanning electron microscope using a plurality of primary charged particle beamlets 3 for generating a plurality of primary charged particle beam spots 5 on a surface 25 of an object 7, such as a wafer or mask substrate located with a top surface in an object plane 101 of an objective lens 102. For simplicity, only three primary charged particle beamlets 3.1 to 3.3 and three primary charged particle beam spots 5.1 to 5.3 are shown. The features and functions of multi-beamlet charged-particle system 1 can be implemented using electrons or other types of primary charged particles such as ions and in particular Helium ions. Further details of the microscope system 1 are provided in International Patent application PCT/EP2021/066255, filed on Jun. 16, 2021, which is hereby fully incorporated by reference.

The system 1 comprises an object irradiation unit 100 and a detection unit 200 and a secondary electron beam divider or beam splitter unit 400 for separating the secondary charged-particle beam path 11 from the primary charged-particle beam path 13. The object irradiation unit 100 comprises a charged-particle multi-beam generator 300 for generating the plurality of primary charged-particle beamlets 3 and is adapted to focus the plurality of primary charged-particle beamlets 3 on the object plane 101, in which the surface 25 of an object 7 is positioned by a sample stage 500.

The primary beam generator 300 produces a plurality of primary charged particle beamlet spots in an intermediate image surface 321. The primary beamlet generator 300 comprises at least one source 301 of primary charged particles, for example electrons. The at least one primary charged particle source 301 emits a diverging primary charged particle beam, which is collimated by at least one collimating lens 303 to form a collimated or parallel primary charged particle beam 309. The collimating lens 303 is usually consisting of one or more electrostatic or magnetic lenses, or by a combination of electrostatic and magnetic lenses. The collimated primary charged particle beam 309 is incident on the primary multi-beam forming unit 305. The multi-beam forming unit 305 basically comprises a first multi-aperture plate or filter plate 304 illuminated by the collimated primary charged particle beam 309. The first multi-aperture plate or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least one further multi-aperture plates 306, which is located, with respect to the direction of movement of the electrons in beam 309, downstream of the first multi-aperture or filter plate 304. For example, a second multi-aperture plate 306 comprises for example four or eight of electrostatic elements for each of the plurality of apertures, for example to deflect each of the plurality of beamlets individually. The multi-beamlet forming unit 305 according to some embodiments is configured with a terminating multi-aperture plate 307. The multi-beamlet forming unit 305 is further configured with an adjacent electrostatic field lenses 308.1, which is in some examples combined in the multi-beamlet forming unit 305. Together with a second field lens 308.2, the plurality of primary charged particle beamlets 3 is focused in or in proximity of the intermediate image surface 321. The primary charged-particle source 301 and each of the active multi-aperture plates 306 are controlled by control unit 800. The plurality of focus points of primary charged particle beamlets 3 passing the intermediate image surface 321 is imaged by field lens group 103 and objective lens 102 into the object plane 101, in which the surface 25 of the object 7 is positioned. A decelerating electrostatic field is generated between the objective lens 102 and the object surface 25 by application of a voltage to the object by the sample voltage supply 503. The object irradiation system 100 further comprises a collective multi-beam raster scanner 110 in proximity of a beam cross over 108 by which the plurality of charged particle beamlets 3 can be deflected in a direction perpendicular to the propagation direction of the charged particle beamlets. The propagation direction of the primary beamlets throughout the examples is in positive z-direction. Objective lens 102 and collective multi-beam raster scanner 110 are centered at an optical axis (not shown) of the multi-beam charged-particle system 1, which is perpendicular to wafer surface 25. The plurality of primary charged particle beamlets 3, forming the plurality of beam spots 5 arranged in a raster configuration, is scanned synchronously over the wafer surface 25. In an example, the raster configuration of the focus spots 5 of the plurality of J primary charged particle 3 is a hexagonal raster of about one hundred or more primary charged particle beamlets 3, for example J=91, J=100, or J approximately 300 or more beamlets. The primary beam spots 5 have a distance about 6 μm to 45 μm and a diameter of below 5 nm, for example 3 nm, 2 nm or even below. In an example, the beam spot size is about 1.5 nm, and the distance between two adjacent beam spots is 8 μm. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets 9 generated at each beam spot 5 depends on the intensity of the impinging primary charged particle beamlet 3, illuminating the corresponding spot 5, the material composition and topography of the object 7 under the beam spot 5, and the charging condition of the sample at the beam spot 5. The plurality of secondary charged particle beamlets 9 are accelerated by the electrostatic field between objective lens 102 and object surface 25 and are collected by objective lens 102 and pass the first collective multi-beam raster scanner 110 in opposite direction to the primary beamlets 3. The plurality of secondary beamlets 9 is scanning deflected by the first collective multi-beam raster scanner 110. The plurality of secondary charged particle beamlets 9 is then guided by secondary electron beam divider or beam splitter unit 400 to follow the secondary beam path 11 of the detection unit 200. The plurality of secondary electron beamlets 9 is travelling in opposite direction from the primary charged particle beamlets 3, and the beam splitter unit 400 is configured to separate the secondary beam path 11 from the primary beam path 13 usually via magnetic fields or a combination of magnetic and electrostatic fields.

Detection unit 200 images the secondary electron beamlets 9 onto the image sensor 600 to form there a plurality of secondary charged particle image spots 15. The detector or image sensor 600 comprises a plurality of detector pixels or individual detectors. For each of the plurality of secondary charged particle beam spots 15, the intensity is detected separately, and the property of the object surface 25 is detected with high resolution for a large image patch of the object 7 with high throughput. For example, with a raster of 10×beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in international patent application WO 2020151904 A2 and in US-Patent U.S. Pat. No. 9,536,702, which are hereby incorporated by reference.

Detection unit 200 further comprises at least a second collective raster scanner 222, which is connected to scanning and imaging control unit 860. Scanning control unit 860 is configured to compensate a residual difference in position of the plurality of focus points 15 of the plurality of secondary electron beamlets 9, such that the positions of the plurality secondary electron focus spots 15 are kept constant at image sensor 600.

The detection unit 200 comprises further electrostatic or magnetic lenses 205.1 to 205.5 and a second cross over of the plurality of secondary electron beamlets 9, in which an aperture 214 is located. The detection unit 200 can further comprise at least a first multi-aperture corrector 216, with apertures and electrodes for individual influencing each of the plurality of secondary electron beamlets 9.

The image sensor 600 is configured by an array of sensing areas in a pattern compatible to the raster arrangement of the secondary electron beamlets 9 focused by the projecting lenses 205 onto the image sensor 600. This enables a detection of each individual secondary electron beamlet independent from the other secondary electron beamlets incident on the image sensor 600. The image sensor 600 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 600 can be configured as electron to photon conversion unit or scintillator plate arranged in the focal plane of the plurality of secondary electron particle image spots 15. In this embodiment, the image sensor 600 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is cited above and incorporated by reference.

During an acquisition of an image patch by scanning the plurality of primary charged particle beamlets 3, the stage 500 might not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

During an image scan, the control unit 800 is configured to trigger the image sensor 600 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

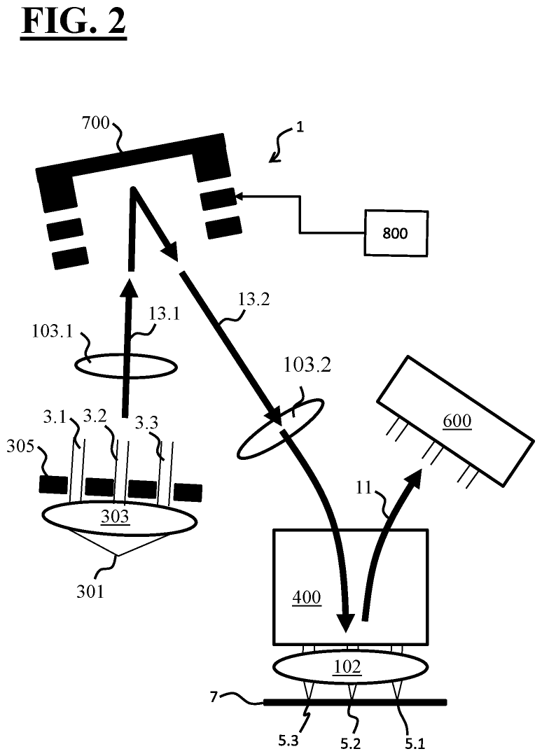

A multi-beam generating unit 305 is for example explained in US 2019/0259575, and in U.S. Pat. No. 10,741,355 B1, both hereby incorporated by reference. In the prior art, the positions of the plurality of focus points of the plurality of primary charged particle beamlets 3 is adjusted in the intermediate image surface 321 by a multi-beam generating unit 305. According to certain known systems, the multi-beam generating unit 305 is the only mechanism to pre-compensate field curvature of optical elements of the object irradiation unit 100 downstream of the multi-beam generating unit 305. The amount of field curvature is adjusted according to the driving parameters of the object irradiation unit 100, for example on the focusing power of the objective lens 102 or the electrostatic field generated between the objective lens 102 and the object surface 25 by the voltage supplied by the sample voltage supply 503, which both are the main sources for field curvature. The compensation of the field the field curvature with the multi-beam generating unit 305 alone is however limited, and thus alternative solutions or additional solutions to compensate field curvature are demanded. Such alternative or additional solutions are provided by the disclosure described in the following examples and embodiments. FIG. 2 schematically illustrates the disclosure at a simplified example. FIG. 2 shows a multi-beam charged-particle system 1 with a charged particle source 301, at least one collimating lens 303 and a primary multi-beamlet forming unit 305. Here, only three primary charged particle beamlets 3.1 to 3.3 are illustrated, but the number can be larger, for example exceeding 100, 300 or even more. The system 1 further comprises a plurality of lens elements comprising at least one objective lens 102 and field lenses 103.1, 103.2 for forming a plurality of focus spots 5 of the plurality of primary beamlets 3 on the surface of a planar object 7. The system 1 further comprises a charged particle mirror element 700, the mirror element 700 being configured for compensating during use a field curvature of the plurality of lens elements 102, 103.1 and 103.2. The charged particle mirror element 700 is configured for reflecting the plurality of primary charged particle beamlets 3 and thus separating the primary beam path 13 into a first primary beam path segment 13.1 between the multi-beam forming unit 305 to the charged particle mirror element 700, and a second primary beam path segment 13.2 of the primary charged particle beamlets 3 after reflection from the charged particle mirror element 700 in direction of the objective lens 102.

The system 1 further comprises a control unit 800. The control unit is configured for providing during use a plurality of voltages the charged particle mirror element 700. The charged particle mirror element 700 and the voltages being configured to generate during use a reflecting lens field with a virtual reflection surface. Further details of a reflecting lens field will be illustrated below. The system according to FIG. 1 further comprises a secondary electron beam divider or beam splitter 400, configured for guiding secondary beamlets, which are generated at the focus spots of the plurality of primary beamlets at the surface of a planar object along the secondary electron beam path 11 to a detector 600.

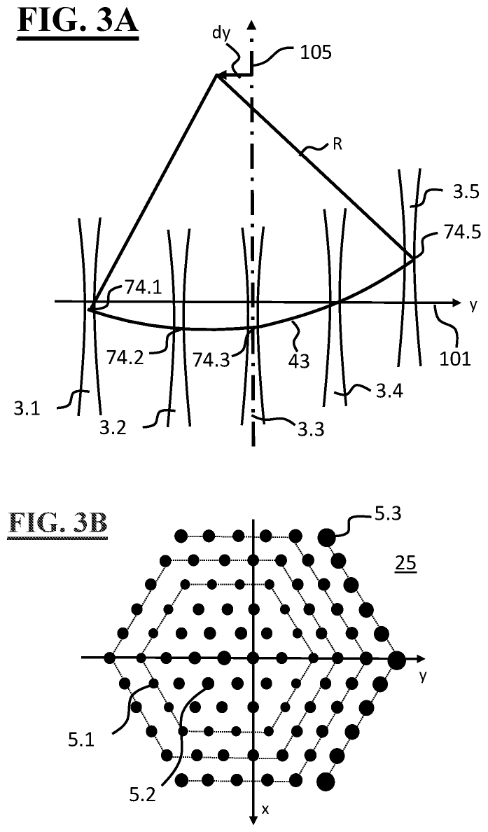

FIGS. 3A-3B illustrate an effect of a field curvature according to the prior art. FIGS. 3A-3B illustrate a plurality of primary beamlets 3.1 to 3.5, with each beamlet having its beam waists 74.1 to 74.5 on a spherically curve surface 43 of radius R. The smallest focus spot sizes 74.1 to 74.5 are identical to the beam waists of beamlets 3.1 to 3.5. Due to an image plane tilt, the center of the sphere 43 can further be decentered from the optical symmetry axis 105. If a planar object 7 such as a mask substrate or wafer is placed in the image plane 101, the primary charged particle focus spots 5, which are identical to the origins of the secondary electrons on the wafer surface 25 are very different, comprising focus spot 5.1 with minimum spot size, focus spot 5.2 with average spot size and focus spot 5.3 with maximum spot size (see FIG. 3B). The spot size variations lead to a different resolution for each secondary electron beamlet 9. There is, however, generally a tight uniformity of resolution for a mask writing or wafer inspection task, for example a resolution provided by each secondary electron beamlet 9 shall not exceed a maximum deviation of for example 10%, or even less, for example 7% or only 5% of the desired resolution. The desired resolution itself can be for example 2 nm or less, for example 1.5 nm. Therefore, field curvature is one of the driving aberrations which limit the performance of multi-beam charged particle systems 1 for imaging tasks, such as multi-beam direct writing of microscopic structures on masks or wafer inspection tasks.

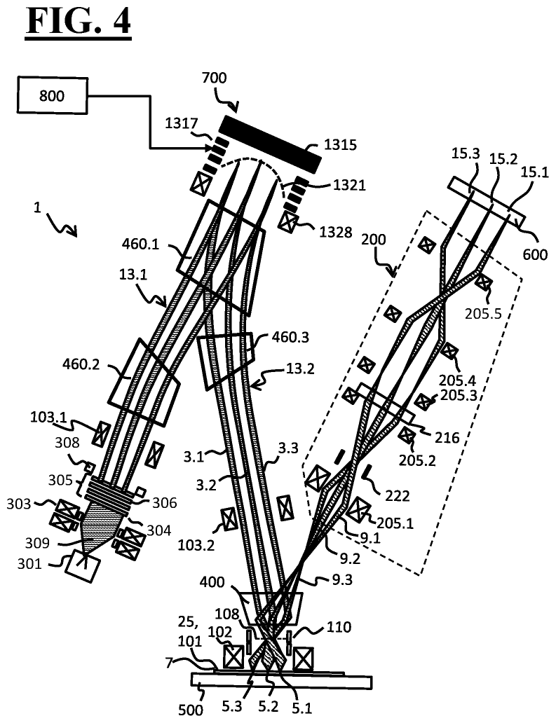

FIG. 4 illustrates a first embodiment of the disclosure. The multi-beam charged particle system 1 according to the first embodiment comprises a charged particle beam source 301 and two collimating lenses 303 for forming a primary charged particle beam 309. The multi-beamlet forming unit 305 forms a plurality of primary charged particle beamlets 3. More details about the multi-beamlet forming unit 305 are described above in conjunction with the example of FIG. 1. The system 1 further comprises a charged particle mirror element 700 with a mirror electrode 1315 and a plurality of further electrodes 1317, configured for forming during use a virtual reflection surface 1321 for reflecting the incident primary charged particle beamlets 3 (only three beamlets 3.1 to 3.3 shown). The mirror electrode 1315 and a plurality of further electrodes 1317 are connected to the control unit 800, which provides predetermined voltages to the mirror electrode 1315 and a plurality of further electrodes 1317.

The system 1 further comprises a primary beam divider 460 for guiding the primary charged particle beamlets 3 along a first beam path 13.1 from the multi-beam forming unit 305 to the charged particle mirror element 700 and configured for guiding the primary charged particle beamlets 3 along a second beam path 13.2 after reflection from the charged particle mirror element 700 in direction of the at least one objective lens 102. The primary beam divider 460 of this example comprises a divider segment 460.1 for dividing the first beam path 13.1 from the second beam path 13.2 and a first segment 460.2 arranged in the first beam path 13.1 and a second segment 460.3 in the second beam path 13.2, the first and the second segment 460.2 and 460.3 being configured for compensating a dispersion and further aberrations of the divider segment 460.1. The system 1 further comprises a common path field lens 1328 in the common beam path between the divider segment 460.1 and the charged particle mirror element 700. The system 1 further comprises at least a first field lens 103.1 in the first beam path 13.1 and at least a second field lens 103.2 in the second beam path 13.2. For the further components of FIG. 4, reference is made to FIG. 1 and the description thereof.

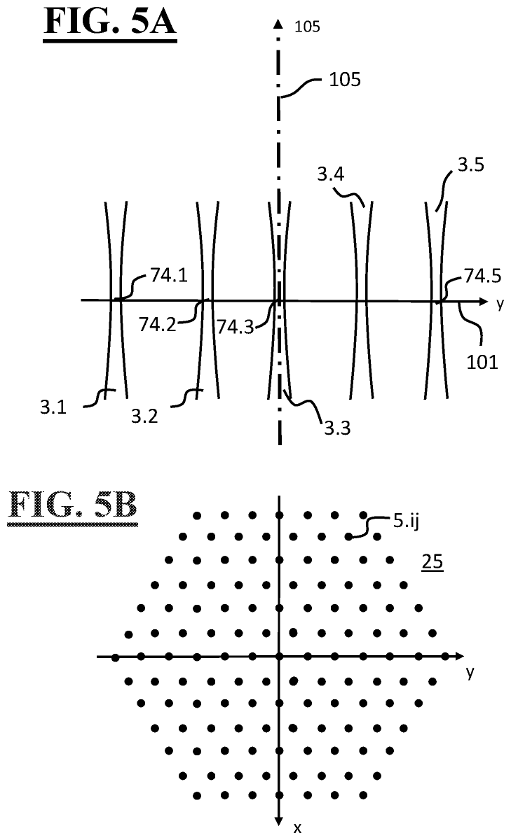

FIGS. 5A-5B illustrate the effect of the disclosure. With a compensation of the field curvature by the charged particle mirror element 700, a system 1 without field curvature is provided and all points of least confusion or beam waists 74.1 to 74.5 are formed in the object plane 101. On a planar surface 25 of an object 7, all focus spots 5.ij have the same minimum diameter. In practice, some minor diameter variations due to residual aberrations might be present, which are below a predetermined threshold. For an even further compensation of the residual diameter variations of the focus spots, the multi-beamlet forming unit 305 can further be provided with a multi-pole array or a lens array 306 for compensation of residual aberrations. Without field curvature, the number J of beamlets can be increased and a higher throughput of the system 1 can be achieved.

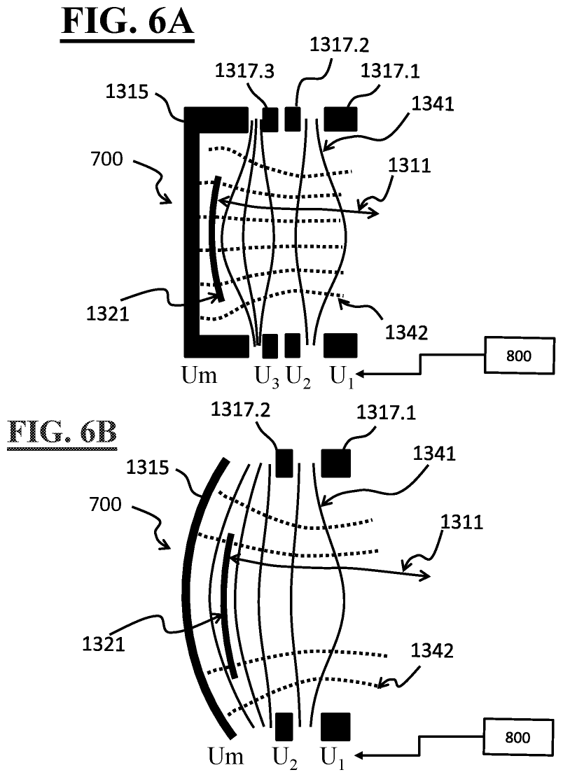

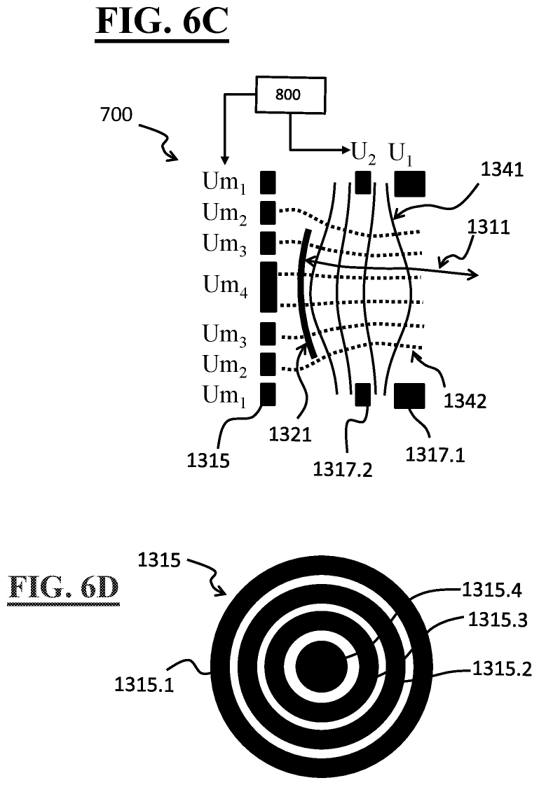

FIGS. 6A-6D illustrate some examples of a charged particle mirror element 700. FIG. 6A shows a first example with a charged particle mirror element 700 comprising three ring electrodes 1317.1 to 1317.3 and one continuous mirror electrode 1315 having a shape of a cup with planar bottom. By the control unit 800, a plurality of voltages U1 to U3 and Um are provided to the electrodes 1317.1 to 1317.3 and 1315, such that incident primary charged particles along for example charged particle path 1311 are decelerated and finally reflected at the virtual mirror surface 1321. The geometry of the electrodes 1317 and 1315 and the voltages U1 to U3 and Um are selected to generate equipotential lines 1341 with electrical field lines 1342 (i-e—the dotted lines), such that the virtual reflection or mirror surface 1321 is formed. The virtual reflection or mirror surface 1321 corresponds to an equipotential surface at which the primary charged particles are decelerated to a kinetic energy of 0 kV. At the virtual reflection surface 1321, the primary charged particles are therefore reflected and accelerated by the electrical field such that the reflected primary charged particles are traveling approximately in opposite direction along path 1311. The voltages are selected according |U1|>|U2|>|U3|>|Um|, with |U1| approximately equal to the kinetic energy of the primary charged particles. |U2| is selected in a range |U1|/5<|U2|<|U1|/3. |U3| is selected in a range |U2|/4<|U3|<|U2|/2. |Um| is selected to a positive voltage with Um˜−1×U3. Thereby, the primary charged particles are decelerated to reach zero kinetic energy at virtual mirror surface 1321 and accelerated in opposite direction to reach again the target kinetic energy of the primary charged particles after reflection. FIG. 6B shows an equivalent example with a curved mirror electrode 1315. FIG. 6C and d show an equivalent example with a segmented mirror electrode 1315, comprising a plurality of ring-shaped segments 1315.1 to 1315.4, to which different mirror voltages Um1 to Um4 are provided to generate during use the virtual mirror surface 1321. For sake of simplicity, only for ring-segments are shown, but the number or ring-segments can be larger. It is also understood that the example is not limited to ring-shaped segments and other shapes are possible as well, for example hexagonal or elliptical segments or a raster of segments with appropriate voltages Um provided to form a virtual reflective surface 1321 of curved shape.

The charged particle mirror element 700 and the voltages provided by the control unit 800 to the electrodes of the charged particle mirror element 700 can further be configured for a change of a field curvature compensation. With different voltages provided by the control unit 800 to the electrodes of the charged particle mirror element 700, the curvature of the virtual reflecting surface can be adjusted. A change of field curvature compensation can for example be desired after a setting change of the multi-beamlet charged-particle system 1, for example after a change of the sample voltage provided by sample voltage supply unit 503 or by a change of magnification by the objective lens 102.

Not only a field curvature can be compensated by a mirror element 700, but also other aberrations of a multi-beam charged particle system 1. An example is a compensation of axial chromatic aberration or dispersion of the plurality of beamlets. The virtual reflection surface 1321 is corresponding to an equipotential surface, suitable for reflecting primary charged particles 3 of a specific, first kinetic energy. For other or a second kinetic energy, the reflection occurs at a different equipotential surface, suitable for reflecting primary charged particles 3 of a specific second kinetic energy. By proper design of the electrodes 1317 including the mirror electrode 1315, a proper shape and sequence of curved virtual reflection surface 1321 for a distribution of kinetic energies of primary charged particles can be configured. Thereby an imaging aberration corresponding to a variance of kinetic energies of primary charged particles is provided.

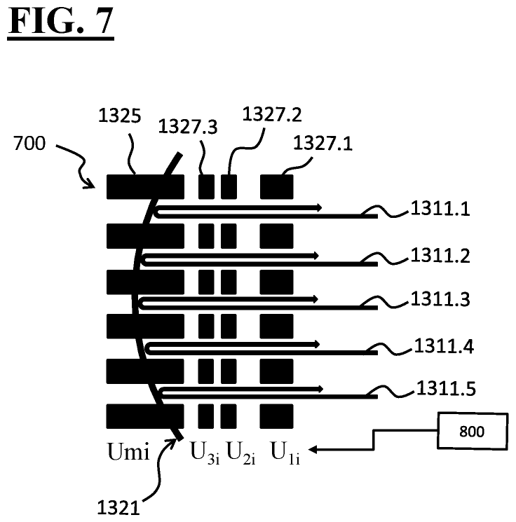

FIG. 7 shows another example of a charged particle mirror element 700. In this example, the charged particle mirror element 700 is configured as an array of mirrors, one mirror for each primary charged particle beamlet, wherein five trajectories 1311.1 to 1311.5 of primary charged particle beamlets are illustrated. The mirror array is formed by multi-aperture plates 1327.1 to 1327.3 and mirror multi aperture plate 1325. In an example, each of the apertures of at least one of the multi-aperture plate 1327.1 to 1327.3 and 1325 is provided with a ring electrode. For example, multi-aperture plate 1327.2 comprises J apertures for a plurality of J primary charged particle beamlets, each aperture provided with a ring electrode. To an ith ring electrode of the ith aperture, a voltage U2i is provided. With voltages U1i to U3i and Umi, for each primary charged particle beamlet, a returning point is adjusted according to a virtual mirror surface 1321.

In an example, the charged particle mirror element 700 according to FIG. 7 is further configured for compensating during use a further imaging aberration. For example, at least one of the multi-aperture plates 1327.1 to 1327.3 comprises multi-pole electrodes instead of a ring-electrode arranged around each aperture, configured for individually correcting an aberration of each beamlet. An example is a compensation of a field-depending astigmatism or coma aberration.

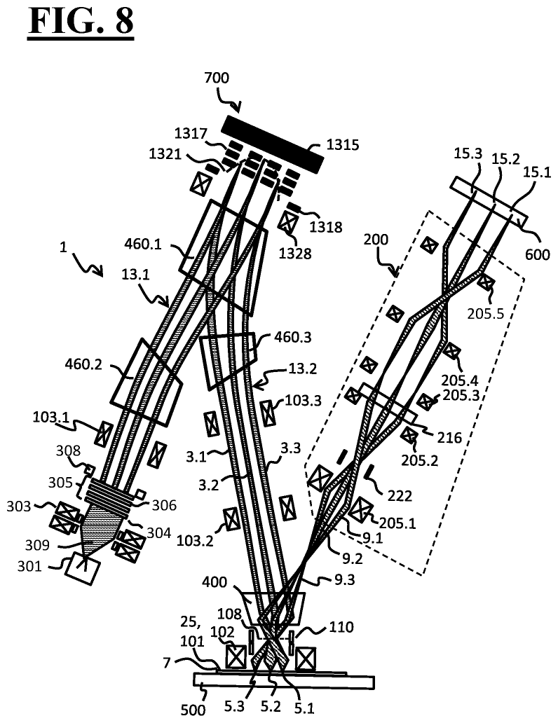

FIG. 8 shows and example of a multi-beam charged particle system 1 according to the first embodiment with a charged particle mirror element 700 configured as a mirror array of FIG. 7. The charged particle mirror element 700 can further comprise a field lens electrode 1318. For the further components of FIG. 8, reference is made to FIG. 4 and the description thereof.

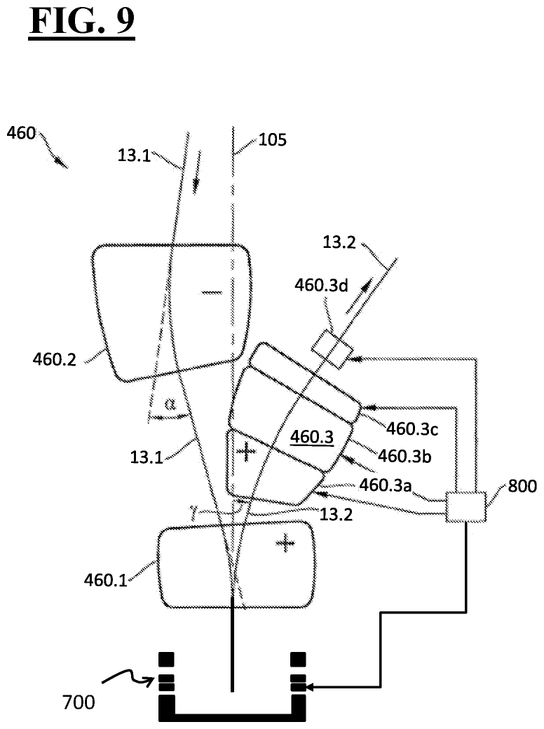

FIG. 9 illustrates an example of a primary beam divider 460. The primary beam divider 460 comprises a divider segment 460.1 for dividing the first beam path 13.1 from the second beam path 13.2 and a first segment 460.2 arranged in the first beam path 13.1 and a second segment 460.3 in the second beam path 13.2, the first and the second segment 460.2 and 460.3 being configured for compensating a dispersion and further aberrations of the divider segment 460.1. In direction of the first beam path 13.1, a charged particle mirror element 700 is arranged and configured to reflect the primary charged particles traveling along the first beam path 13.1 into the second beam path 13.2. The second segment 460.2 comprises three magnetic sectors 460.3a to 460.3c and on electrostatic element 460.3d. All elements are connected to control unit 800, which is configured to provide corresponding voltages and currents to the elements of the primary beam divider 460 and the charged particle mirror element 700.

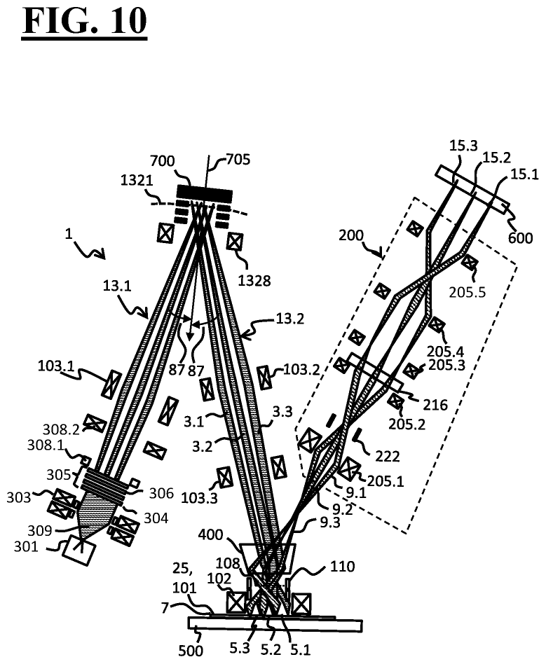

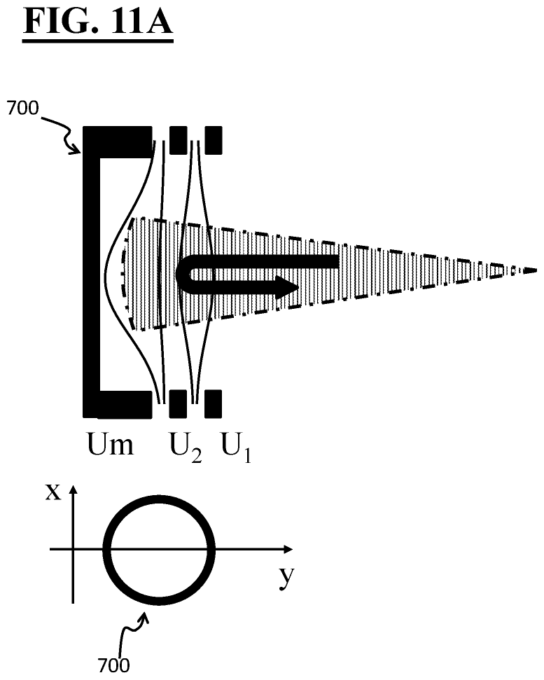

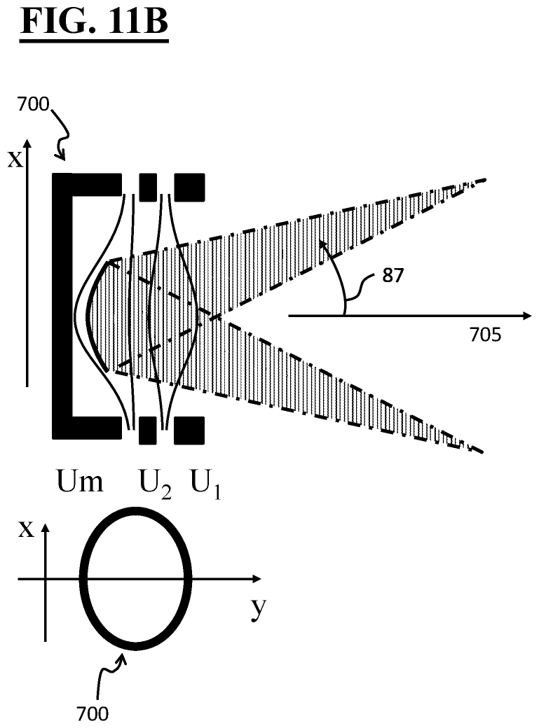

The examples according to the first embodiment are configured for a reflection in normal incidence at the charged particle mirror element 700. The examples of the first embodiment therefore implement a beam divider 460 for the beam path separation between the first and second beam paths 13.1 and 13.2. In the second embodiment, a primary beam divider 460 is not required and a reflection at oblique incidence is used at the charged particle mirror element 700. FIG. 10 shows a second embodiment of the disclosure. Same elements are labelled with same reference numbers and reference is made to FIG. 4 and the description thereof. Opposite to FIG. 4, the example according to FIG. 10 does not have the primary beam divider 460 according to the first embodiment. Instead, system 1 is configured for an oblique angle of incidence 87 with respect to the normal 705 of the charged particle mirror element 700. The primary charged particles traveling along the first beam path 13.1 are reflected at the virtual mirror surface 1321 of the charged particle mirror element 700 into the second beam path at the same oblique angle 87 with respect to the mirror normal 705. For a separation of the first and second beam paths 13.1 and 13.2, the oblique angle 87 is selected to exceed 5°, for example 10°. The first and second paths 13.1 and 13.2 are arranged at an angle twice as large as the oblique angle of incidence 87. The first and second paths 13.1 and 13.2 are thus arranged at an angle exceeding 10°, for example at 15° or even 20°. FIG. 11B illustrates an example of a charged particle mirror element 700 configured for oblique incidence at angle 87 with respect to the mirror normal 705. The mirror 700 is configured similar to a mirror 700 of FIGS. 6a-d, but has an elliptical cross section shown in the lower part of FIG. 11B. Thereby, an astigmatism generated at the oblique incidence at angle 87 at a circular mirror is compensated. An example with a circular mirror 700 configured for normal incidence is illustrated in FIG. 11A.

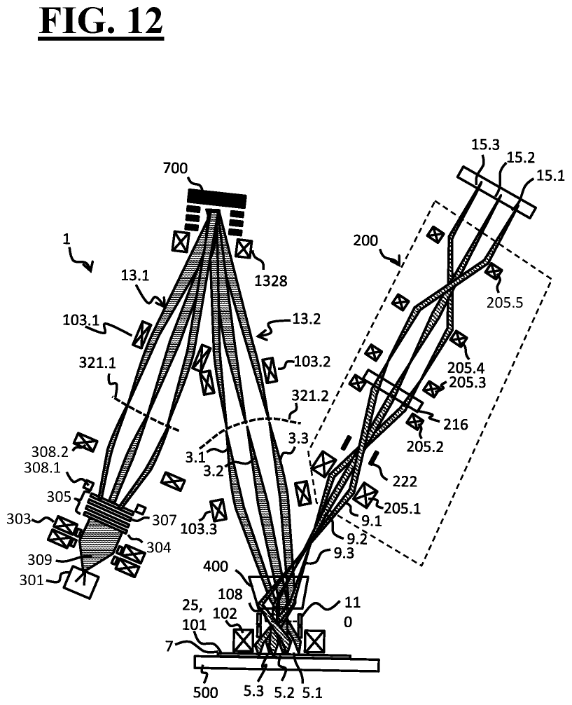

FIG. 12 shows another example according to the second embodiment. Same elements are labelled with same reference numbers and reference is made to FIG. 10 and the description thereof. The system 1 is configured to generate a first intermediate image surface 321.1 in the first beam path 13.1, upstream of the charged particle mirror element 700. The charged particle mirror element 700 is placed in a pupil plane, and a second intermediate image surface 321.2 is formed in the second beam path 13.2, downstream of the charged particle mirror element 700. By action of the charged particle mirror element 700, the second intermediate image surface 321.2 is formed in a curved shape configured to compensate a field curvature of the optical elements downstream of the second intermediate image surface 321.2, including the objective lens 102 and at least one field lens 103.3.

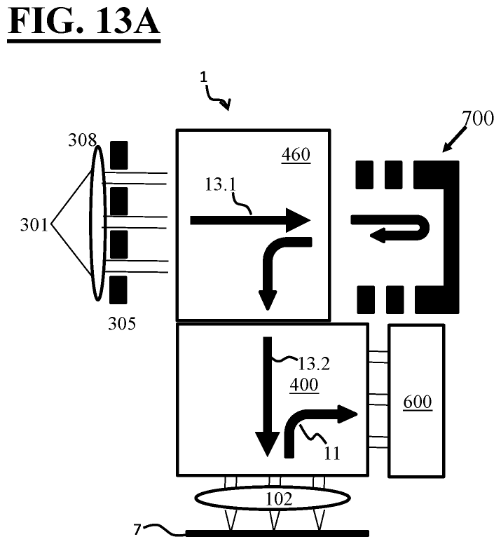

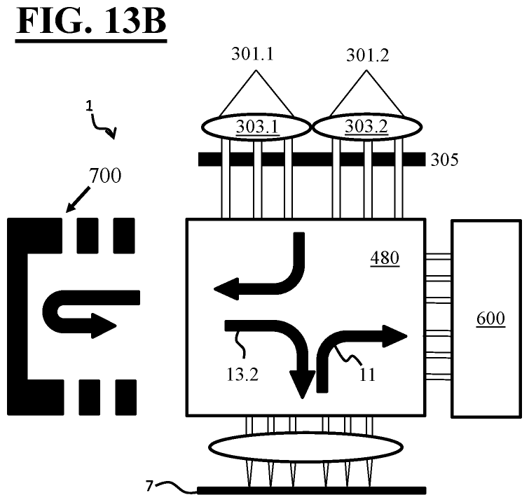

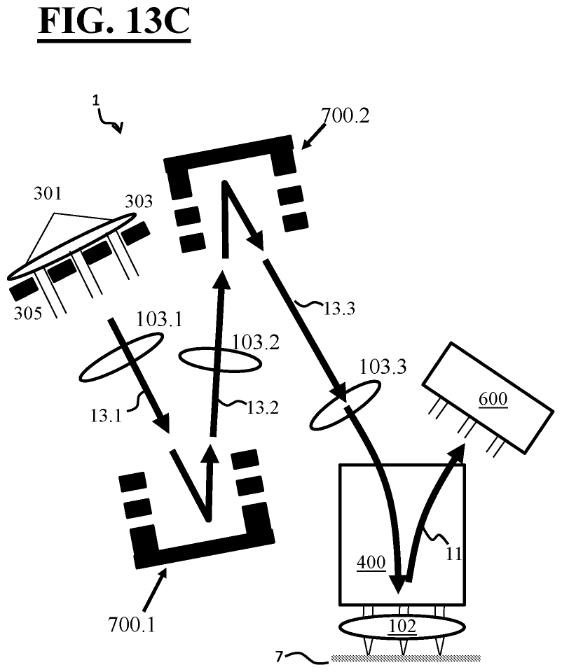

FIG. 13A illustrates a further variation of the first embodiment. Here, the primary beam divider 460 and the beam splitter unit 400 are arranged adjacent to each other. In an example of FIG. 13B, the primary beam divider 460 and the beam splitter unit 400 are formed as one unit 480. FIG. 13C illustrates a third embodiment similar to the second embodiment. Here, a first charged particle mirror element 700.1 and a second charged particle mirror element 700.2 is arranged in the primary beam path 13, comprising a first beam path segment 13.1, a second beam path segment 13.2 and a third beam path segment 13.3. With two reflective charged particle mirror elements 700.1 and 700.2, a compensation of a field curvature can further be improved.

With the mirror element 700 according to the embodiments of the disclosure, a field curvature is compensated and a focus deviation of focus spots 5 of the plurality of beamlets 3 is not limiting the number of beamlets J or the field size anymore. Therefore, with a mirror element 700, a larger number J of beamlets, for example J>300, J>1000 or even J>10000 is possible. To supply sufficient charged particle beam current to each beamlet 3, it is also possible to use several charged particle beam sources in one multi-beam charged particle system 1. An example is illustrated in FIG. 13B with two charged particle sources 301.1 and 301.2 with two condenser lens systems 303.1 and 303.2 provided upstream of multi-beam forming unit 305.

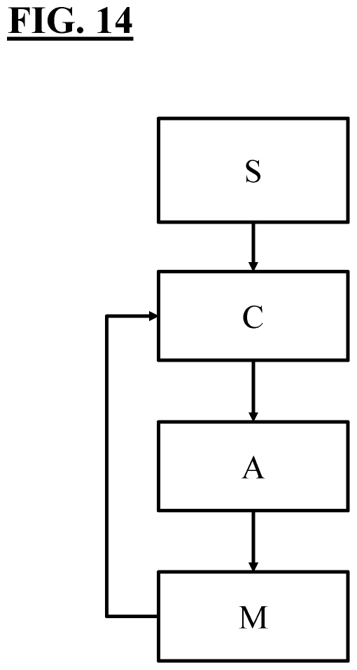

FIG. 14 illustrates a method of operation of a multi-beam charged particle system 1 with at least one first charged particle mirror element 700. In an initial step S, a setting of parameters of a multi-beam charged particle system 1 is selected. The parameters of a multi-beam charged particle system 1 comprise for example a setting of the objective lens 102, a landing energy of primary charged particles selected by the voltage provided by sample voltage supply 503, or a setting of field lenses 103 to compensate for a rotation of the plurality of primary beamlets 3. The setting of the parameters in step S might induce a change of the field curvature of the surface 43 (see FIGS. 3A-3B) on which the focus spots 5 of minimum spot diameter are formed.

In compensation step C, the specific radius R of the field curvature for the selected parameter settings of step S is determined. The radius R of the field curvature for a plurality of parameter settings can be stored in a memory of the control unit 800 or can be computed for example from the driving currents provided to the lens elements 103 and 102 according to predetermined mathematical lens models. For the specific radius R of the field curvature, a control signal for a plurality of driving voltages U and Um of the charged particle mirror element 700 is computed by control unit 800. The plurality of driving voltages U and Um comprise for example the voltages U1 to U3 for the ring electrodes 1317.1 to 1317.3 and at least one voltage Um for the at least one segment of the mirror electrode 1315. In another example, driving voltages comprise a plurality of driving voltages Uli with i=1 . . . J (with J being the number of primary beamlets) for at least one multi-aperture plate 1327 (see examples of FIGS. 6a-d and 7). Furthermore, other control signals and voltages for compensation of other aberrations by the charged particle mirror element 700 can be generated by control unit 800 and provided to the charged particle mirror element 700. Off course, the other elements of the multi-beam charged particle system 1 are driven and controlled as well by control unit 800, as known from systems of the prior art.

In application step A, an application of the multi-beam charged particle system 1 is performed. Such an application can be the performance of an inspection task of for example a semiconductor wafer, or the performance of a multi-beam lithography task, such as a patterning of a semiconductor mask. A metrology step M is triggered by control unit 800 to control the performance of the multi-beam charged particle system 1. Thereby, the performance of the charged particle mirror element 700 is controlled and eventually adjusted in a repetition of the method beginning with step C.

The metrology step M can also be performed either before or during the performance of the task in step A, and the correction of a field curvature and other aberrations by charged particle mirror element 700 can be monitored during application step A. generally, during monitoring step M, a performance of the multi-beam charged particle system 1 and a residual aberration is determined. Based on the residual aberration, a control step can be triggered, and corrected driving voltages configured for compensating the residual aberration can be determined and provided to at least one electrode of the charged particle mirror element 700.

With the method of operation of the multi-beam charged particle system 1 and the configuration of the charged particle mirror element 700, a variable compensation of a field curvature is enabled. The field curvature is depending on a parameter setting of a multi-beam charged particle system 1, and the design of the charged particle mirror element 700 and the voltages provided by a control unit 800 to drive the charged particle mirror element 700 are configured to variably compensate field curvature and optionally other aberrations.

The features of the embodiments improve the performance of a multi-beam charged particle system 1 to achieve higher resolution of below 5 nm, such as below 3 nm, for example below 2 nm or even below 1 nm. The improvements are of special relevance for a further development of multi-beam charged particle systems with a larger number of the plurality of primary beamlets such as more than 100 beamlets, more than 300 beamlets, more than 1000 beamlets or even more than 10000 beamlets. The improvements are of special relevance for routine applications of multi-beam charged particle systems, for example in mask writing applications or in semiconductor inspection and review, where high reliability and high reproducibility and low machine-to-machine deviations are desired. With the features described in the embodiments as well as combinations thereof, each beamlet of the plurality of beamlets is provided with beamlet diameters for example in a span from 2 nm to 2.1 nm with an average resolution of 2.05 nm, and the range of resolution achieved by the features and methods of the embodiments is below 0.15% of the average resolution, such as 0.1%, for example 0.05%.

The disclosure is further described by following clauses:

Clause 1: A multi-beam charged particle system (1), comprising

an object irradiation unit (100), wherein the object irradiation unit (100) comprises
a charged particle beam source (301)
a multi-beam forming unit (305) for forming plurality of primary beamlets (3, 3.1, 3.2, 3.3);
a plurality of lens elements (102, 103, 103.1, 103.2, 103.3) comprising at least one objective lens (102) for forming a plurality of focus spots (5, 5.1, 5.2, 5.3) of the plurality of primary beamlets (3, 3.1, 3.2, 3.3) in an image plane (101);
a charged particle mirror element (700), the charged particle mirror element (700) being configured for compensating during use a field curvature of the plurality of lens elements (102, 103, 103.1, 103.2, 103.3).

Clause 2: The multi-beam charged particle system (1) according to clause 1, further comprising
a control unit (800), and wherein
   the control unit (800) is configured for providing during use a plurality of voltages (U1, U2, U3, Um) to the charged particle mirror element (700), wherein the charged particle mirror element (700) and the voltages (U1, U2, U3, Um) being configured to generate during use a reflecting lens field distribution with a virtual reflection surface (1321).

Clause 3: The multi-beam charged particle system (1) according to clause 2, wherein the charged particle mirror element (700) comprises at least three electrodes (1317.1, 1317.2, 1315), comprising at least a first and a second ring shaped electrode electrodes (1317.1, 1317.2) and a mirror electrode (1315), connected to the control unit (800), and wherein the control unit (800) is configured for providing during use a first voltage U1 to the first ring shaped electrode (1317.1), a second voltage U2 to the second ring shaped electrode (1317.2) and a mirror voltage Um to the mirror electrode (1315), the electrodes and the voltages being configured to generate during use the virtual reflection surface (1321).

Clause 4: The multi-beam charged particle system (1) according to clause 3, wherein the mirror electrode (1315) has a curved shape.

Clause 5: The multi-beam charged particle system (1) according to clause 3 or clause 4, wherein the mirror electrode (1315) is a segmented electrode comprising a plurality of N electrode segments (1315.1 to 1315.N), and wherein the control unit (800) being further configured for providing during use a plurality of mirror voltages Um1 to UmN to the plurality of N electrode segments (1315.1 to 1315.N).

Clause 6: The multi-beam charged particle system (1) according to any of the clauses 3 to 5, wherein the charged particle mirror element (700) comprises a third electrode (1317.3) connected to the control unit (800), the control unit (800) being further configured for providing during use a third voltage U3 to the third ring shaped electrode (1317.3).

Clause 7: The multi-beam charged particle system (1) according to any of the clauses 3 to 6, wherein the charged particle mirror element (700) is arranged in a plane where the plurality of primary charged particle beamlets (3) are at least partially overlapping.

Clause 8: The multi-beam charged particle system (1) according to any of the clauses 3 to 6, wherein the charged particle mirror element (700) is arranged in proximity of an intermediate field plane, where a plurality of focus spots is formed.

Clause 9: The multi-beam charged particle system (1) according to clause 8, wherein the charged particle mirror element (700) comprises a plurality of multi-aperture plates (1327.1, 1327.2, 1327.3, 1325) with a plurality of apertures, configured to individually receive and reflect each individual primary charged particle beamlet (3) of the plurality of primary charged particle beamlets (3).

Clause 10: The multi-beam charged particle system (1) according to any of the clauses 8 to 9, wherein the charged particle mirror element (700) is configured for a normal incidence of the plurality of primary beamlets (3), such that the reflected primary beamlets are propagating approximately in parallel direction to the incident primary beamlets.

Clause 11: The multi-beam charged particle system (1) according to clause 10, further comprising
a primary charged particle beam divider (460) for guiding the primary charged particle beamlets (3) along a first beam path (13.1) from the multi-beam forming unit (305) to the charged particle mirror element (700), and configured for guiding the primary charged particle beamlets (3) along a second beam path (13.2) after reflection from the charged particle mirror element (700) in direction of the at least one objective lens (102).

Clause 12: The multi-beam charged particle system (1) according to clause 10, wherein the primary charged particle beam divider (460) comprises
a divider segment (460.1) for dividing the first beam path (13.1) from the second beam path (13.2),
at least a first segment (460.2) arranged in the first beam path (13.1),
at least a second segment (460.3) in the second beam path (13.2), the first and the second segment (460.2, 460.3) being configured for compensating a dispersion and further aberrations of the divider segment (460.1).

Clause 13: The multi-beam charged particle system (1) according to any of the clauses 1 to 7, wherein the charged particle mirror element (700) is configured for an oblique angle of incidence (87), forming a first path (13.1) from the multi-beam forming unit (305) to the charged particle mirror element (700), a forming a second path (13.2) of the primary charged particle beamlets (3) after reflection from the charged particle mirror element (700) in direction of the at least one objective lens (102), wherein the first and second path (13.1, 13.2) are arranged at an angle exceeding 15° with respect to each other.

Clause 14: The multi-beam charged particle system (1) according to clause 13, wherein the charged particle mirror element (700) has an elliptical cross section.

Clause 15: The multi-beam charged particle system (1) according to any of the clauses 1 to 14, further comprising
a secondary electron beam divider (400) configured for guiding secondary beamlets (9), which are generated at the focus spots (5) of the plurality of primary beamlets (3) at the surface (25) of a planar object (7) to a detector (700).

Clause 16: The multi-beam charged particle system (1) according to clause 15, further comprising a secondary electron imaging system (200) comprising a plurality of lens elements (205.1, 205.2, 205.3, 205.4, 205.5).

Clause 17: The multi-beam charged particle system (1) according to clause 15 or 16, wherein the primary charged particle beam divider (460) and the secondary electron beam divider (400) is formed as one integrated unit (480).

Clause 18: The multi-beam charged particle system (1) according to any of the clauses 1 to 17, further comprising a second charged particle mirror element (700.2), the first and the second mirror element (700.1, 700.2) being configured for compensating during use a field curvature of the plurality of lens elements (103.1, 103.2, 103.3, 102).

Clause 19: The multi-beam charged particle system (1) according to any of the clauses 1 to 18, wherein the charged particle mirror element (700) is further configured for compensating during use a further imaging aberration of at least one of the primary beamlets (3, 3.1, 3.2, 3.3).

Clause 20: A method of operating a multi-beam charged particle system (1) comprising a charged particle mirror element (700), comprising
step S: selecting a parameter setting of the multi-beam charged particle system (1);
step C: determining a field curvature of the multi-beam charged particle system (1) with the selected parameter setting; determining at least a driving voltage configured for compensating the field curvature, and providing the driving voltage to the at least one electrode of the charged particle mirror element (700);
step A: performing a application of the multi-beam charged particle system (1).

Clause 21: The method according to clause 20, further comprising step M of monitoring a performance of the multi-beam charged particle system (1) and determining a residual aberration.

Clause 22: The method according to clause 21, further comprising the step of determining at least a corrected driving voltage configured for compensating the residual aberration and providing the corrected driving voltage to the at least one electrode of the charged particle mirror element (700).

Clause 23: The method according to any of the clauses 20 to 22, wherein the application is one of a wafer inspection or a mask writing task.

The disclosure is not limited to the embodiments or clauses described above. The embodiments or examples can be fully or partly combined with one another, and numerous variations and modifications are possible. Despite some improvements are described at the example of multi-beam charged particle systems for inspection, the improvements are not limited thereto, but also applicable to other multi-beam charged particle systems such as multi-beam lithography systems, for example for mask writing applications.

Throughout the embodiments, electrons are to be understood as charged particles in general. While some embodiments are explained at the example of electrons, they shall not be limited to electrons but well applicable to all kinds of charged particles, such as for example Helium or Neon-Ions.

A list of reference numbers is provided:
1 multi-beamlet charged-particle system
3 primary charged particle beamlets
5 primary charged particle beam spot
7 object
9 secondary electron beamlets
11 secondary electron beam path
13 primary charged particle beam path
15 secondary electron image spot
25 surface of object
43 spherically curved surface
74 beam waist
87 oblique angle of incidence
100 object irradiation unit
101 image plane
102 objective lens
103 field lens
105 optical axis of multi-beamlet charged-particle system 1
108 first beam cross over
110 collective multi-beam raster scanner
200 detection unit
205 lens element
214 aperture filter
216 active element
222 second deflection system
300 charged-particle multi-beamlet generator
301 charged particle source
303 collimating lenses
304 filter plate
305 primary multi-beamlet-forming unit
306 multi-aperture plates
307 terminating multi-aperture plate
308 field lenses
309 primary electron beam
321 intermediate image surface
400 beam splitter unit
460 primary beam divider
480 integrated primary and secondary charged particle divider unit
500 sample stage
503 sample voltage supply
600 image sensor
700 charged particle mirror element
705 normal axis to charged particle mirror element
800 control unit
860 scanning control unit
1311 charged particle beam paths or trajectories
1315 mirror electrode
1317 electrodes
1318 field lens electrode
1321 virtual reflection surface
1328 common path field lens
1341 equipotential lines
1342 electrical field lines

1. A multi-beam charged particle system, comprising:
an object irradiation unit, comprising:
a charged particle beam source configured to provide a primary charged particle beam;
a multi-beam forming unit configured to form a plurality of primary beamlets from the primary charged particle beam;
a plurality of lens elements comprising an objective lens, the objective lens configured to generate a plurality of focus spots of the plurality of primary beamlets in an image plane;
a chargeable particle mirror element configured so that, when charged during use of the multi-beam charged particle system, the particle mirror element compensates a field curvature of the plurality of lens elements.

2. The multi-beam charged particle system of claim 1, further comprising a control unit configured to provide a plurality of voltages to the particle mirror element to generate a reflecting lens field distribution with a virtual reflection surface.

3. The multi-beam charged particle system of claim 2, wherein:
the particle mirror element comprises a first ring shaped electrode, a second ring shaped electrode and a mirror electrode;
the control unit is configured to provide: i) a first voltage to the first ring shaped electrode; ii) a second voltage to the second ring shaped electrode; and iii) a mirror voltage to the mirror electrode to generate the virtual reflection surface.

4. The multi-beam charged particle system of claim 3, wherein the mirror electrode comprises a curved shape.

5. The multi-beam charged particle system of claim 3, wherein:
the mirror electrode comprises a segmented electrode;
the segmented electrode comprises a plurality of electrode segments;
the control unit is configured to provide a plurality of voltages with each electrode segment having a corresponding voltage provided thereto.

6. The multi-beam charged particle system of claim 3, wherein the particle mirror element comprises a third ring shaped electrode, and the control unit if configured to provide a third voltage to the third ring shaped electrode.

7. The multi-beam charged particle system of claim 3, wherein the particle mirror element is in a plane in which the plurality of primary charged particle beamlets at least partially overlap.

8. The multi-beam charged particle system of claim 3, wherein the particle mirror element is arranged is proximity to an intermediate field plane in which a plurality of focus spots is formed.

9. The multi-beam charged particle system of claim 8, wherein the particle mirror element comprises a plurality of multi-aperture plates comprising a plurality of apertures configured to individually receive and reflect each individual primary charged particle beamlet of the plurality of primary charged particle beamlets.

10. The multi-beam charged particle system of claim 8, wherein the particle mirror element is configured so that the primary beamlets are normally incident on the particle mirror element so that the reflected primary beamlets propagate approximately in parallel direction to the incident primary beamlets.

11. The multi-beam charged particle system of claim 10, further comprising a primary charged particle beam divider configured to guide the primary charged particle beamlets along: i) a first beam path from the multi-beam forming unit to the particle mirror element; and
ii) a second beam path after reflection from the particle mirror element toward objective lens.

12. The multi-beam charged particle system of claim 10, wherein the primary charged particle beam divider comprises:
a divider segment configured to divide the first beam path from the second beam path;
a first segment in the first beam path; and
a second segment in the second beam path,
wherein the first and the second segments are configured to compensate a dispersion and further aberrations of the divider segment.

13. The multi-beam charged particle system of claim 1, wherein the charged particle mirror element is configured so that:
a first path of the plurality of primary beamlets extends from the multi-beam forming unit to the particle mirror element so that the plurality of primary beamlets impinge obliquely on the particle mirror element;
a second path of the primary charged particle beamlets after reflection from the particle mirror element extends from the particle mirror element towards the objective lens; and
an angle between the first and second paths is greater than 15°.

14. The multi-beam charged particle system of claim 13, wherein the particle mirror element comprises an elliptical cross section.

15. The multi-beam charged particle system of claim 1, further comprising a secondary electron beam divider configured to guide secondary beamlets generated at the focus spots of the plurality of primary beamlets at a surface of a planar object to a detector.

16. The multi-beam charged particle system of claim 15, further comprising a secondary electron imaging system comprising a plurality of lens elements.

17. The multi-beam charged particle system of claim 15, wherein the primary and secondary charged particle beam dividers define an integrated unit.

18. The multi-beam charged particle system of claim 1, further comprising a second chargeable particle mirror element, wherein the first and the second mirror elements are configured to compensate a field curvature of the plurality of lens elements.

19. The multi-beam charged particle system of claim 1, wherein the particle mirror element is configured to compensate an imaging aberration of at least one of the primary beamlets.

20. A method of operating a multi-beam charged particle system which comprises a chargeable particle mirror element, the method comprising:
selecting a parameter setting of the multi-beam charged particle system;
determining a field curvature of the multi-beam charged particle system with the selected parameter setting;
determining a driving voltage to compensate the field curvature;
providing the driving voltage to at least one electrode of the particle mirror element; and
performing an application of the multi-beam charged particle system.

21.-23. (canceled)
